(19) United States
(12) Patent Application Publication
(10) Pub. No.: US 2009/0008755 A1
(43) Pub. Date: Jan. 8, 2009

(54) STRUCTURE AND METHOD FOR MANUFACTURING SMD DIODE FRAME

(75) Inventor: WAN-SHUN CHOU, TAIPEI (TW)

Correspondence Address: ROSENBERG, KLEIN & LEE, 3458 ELLICOTT CENTER DRIVE-SUITE 101, ELLICOTT CITY, MD, 21043, US

(73) Assignee: I-CHIUN PRECISION INDUSTRY CO., LTD., TAIPEI (TW)

(21) Appl. No.: 11/773,630

(22) Filed: Jul. 5, 2007

(51) Int. Cl. H01L 23/495; H01R 43/00

(52) U.S. Cl. 257/676; 29/827; 257/E23.031

(57) ABSTRACT

A structure of an SMD (surface mount device) diode frame is provided that comprises a plastic seat and a plurality of metal pins. One side of the plastic seat has a concave functional area and the other side of the plastic seat corresponding to the functional area has a plurality of concave reserved holes. The functional area and the reserved holes are respectively formed via a forming bolt and a positioning bolt in a mold. If the forming bolt and the positioning bolt abut against the metal pins respectively, the preciseness of the size of the functional area is increased and the overflow of the material of the plastic seat is decreased. Furthermore, the yield of the manufacturing processes is improved.

### BACKGROUND OF THE INVENTION

1. Field of the Invention

The present invention relates to a structure and method for manufacturing an SMD diode frame, and more particularly, to a method that uses a forming bolt and positioning bolts that respectively abut against metal pins to form an SMD diode frame.

2. Description of Related Art

LEDs (Light Emitting Diodes) have a number of advantages such as their small size, being shake-resistant, low electricity use, short reaction times, long user life, and so on for. They have been widely used for a number of years now. Recently, LEDs have become widely used as illumination devices and backlights for all kinds of products.

For a conventional SMD LED, the LED chip is disposed on the SMD diode frame to form an SMD LED via a wire bonding and packaging method. The diode frame has a plastic seat and a plurality of metal pins. One side of the plastic seat has a concave functional area. The metal pins are respectively connected to the plastic seat and the metal pins extend out of the plastic seat from the concave functional area.

As shown in FIG. 1, the metal substrate is formed with a metal pin 11′ by punching and being placed into a mold 20′. The metal pin 11′ is disposed into a molding cavity of the mold 20′, and a forming bolt 21′ abuts against the metal pin 11′. Polymer material 3′ is poured into the molding cavity to solidify and form a plastic seat 30′. The functional area is formed via the forming bolt 21′. However, the metal pin 11′ cannot be attached securely, and the metal pin 11′ is displaced due to the polymer material 3′ flowing into the mold 20′. The polymer material 3′ overflows between the forming bolt 21′ and the metal pin 11′. The size of the functional area is not easily controlled and the yield is low. Therefore, the quality of the product is unreliable and costs are high.

Accordingly, as discussed above, the prior art still has some drawbacks that could be improved. The present invention aims to resolve the drawbacks in the prior art.

### SUMMARY OF THE INVENTION

An object of the present invention is to provide a structure and a method for manufacturing an SMD diode frame that prevents the metal pins from being displaced or overflowing. Moreover, the size of the functional area can be easily controlled, the yield is high, the quality of the product is reliable, and cheap to produce.

For reaching the objects above, the present invention provides a method for manufacturing an SMD diode frame, comprising: providing and punching a metal substrate to form a plurality of metal pins which are disposed at intervals and are not connected together; providing a mold having a predetermined shaped molding cavity, wherein the molding cavity has a forming bolt and a corresponding plurality of positioning bolts; positioning the metal substrate in the mold to the metal pins disposed in the molding cavity, wherein the forming bolt and the positioning bolts respectively abut against two opposite sides of the metal pins; providing and pouring a polymer material into the molding cavity to cover the forming bolt, the positioning bolts, and the metal pins; cooling and solidifying the polymer material to form an insulating plastic seat; and removing the forming bolt and the positioning bolts to obtain the metal substrate from the mold, wherein on one side of the plastic seat a concave functional area is formed via the forming bolt, and on the opposite side of the plastic seat a plurality of reserved holes is formed via the positioning bolts. Further, metal pins respectively extend outwardly outside of the plastic seat from the functional area, and the reserved holes communicate with the side of the metal pins.

The present invention provides a structure for an SMD diode frame, comprising: a plastic seat, wherein one side of the plastic seat has a concave functional area and the opposite side of the plastic seat has a plurality of concave reserved holes; and a plurality of metal pins respectively disposed on the plastic seat at intervals and respectively extending outwardly to the outside of the plastic seat from the functional area, and the reserved holes communicate with the side of the metal pins.

The advantages of the invention are: the forming bolt and the positioning bolts respectively abut against two opposite sides of the metal pins in order that the metal pins are attached in the molding cavity so that the size of the functional area is accurate, the yield high and costs can be kept low.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a cross-sectional view of the SMD diode frame of the prior art;

FIG. 2 is a flowchart of the method of the present invention;

FIG. 3 is a perspective view of the metal substrate of the present invention;

FIG. 4 is a cross-sectional view of the metal pins of the present invention;

FIG. 5 is a cross-sectional view of the plastic seat of the present invention;

FIG. 6 is a perspective view of the functional area of the present invention;

FIG. 7 is a perspective view of the reserved holes of the present invention;

FIG. 8 is a perspective view of the metal pins of the present invention; and

FIG. 9 is a perspective view of the die and wire bond of the present invention.

### DETAILED DESCRIPTION OF PREFERRED EMBODIMENTS

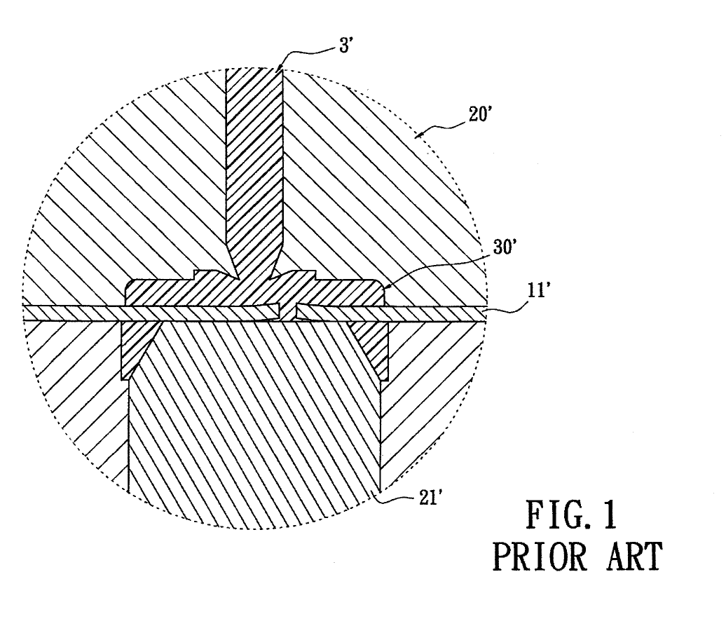

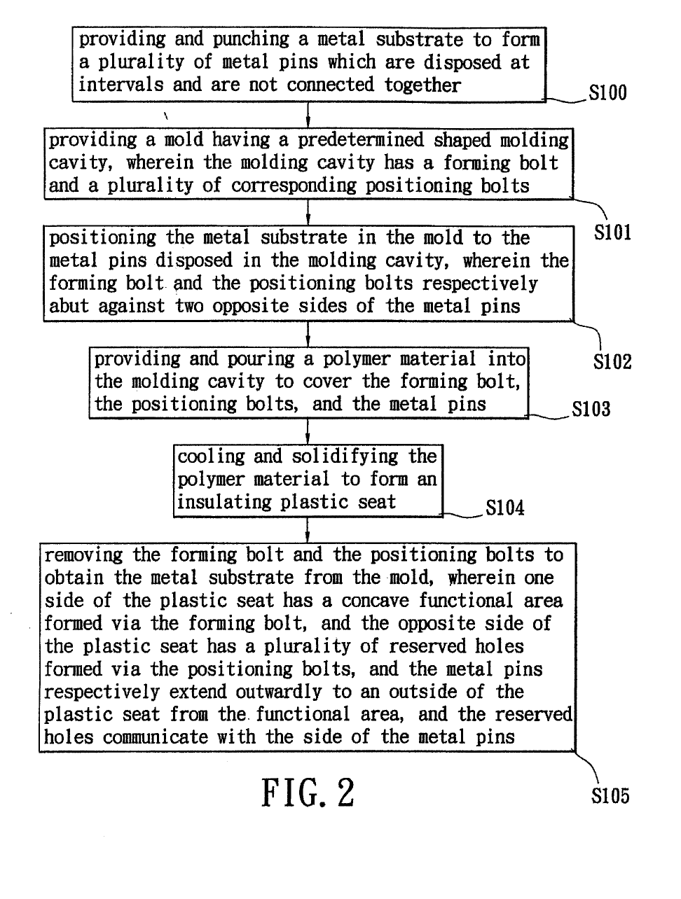

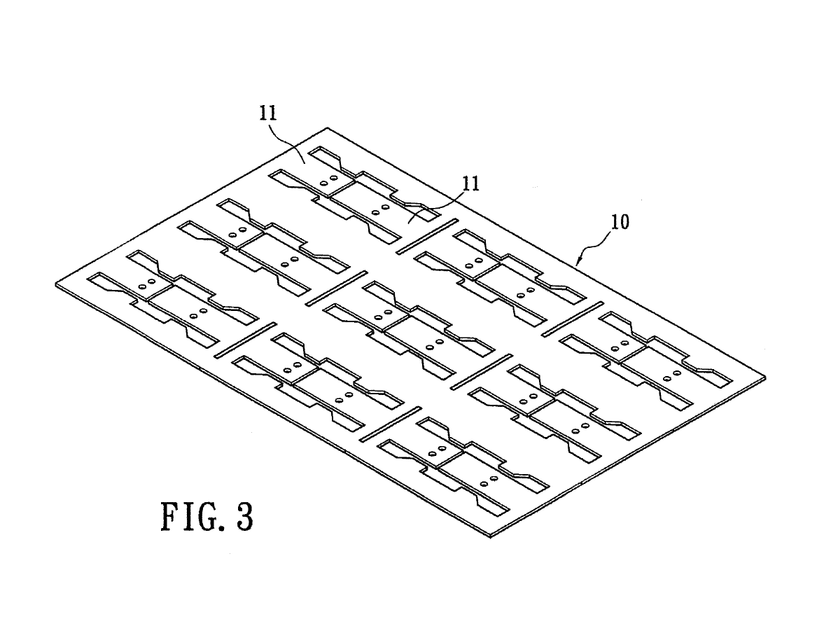

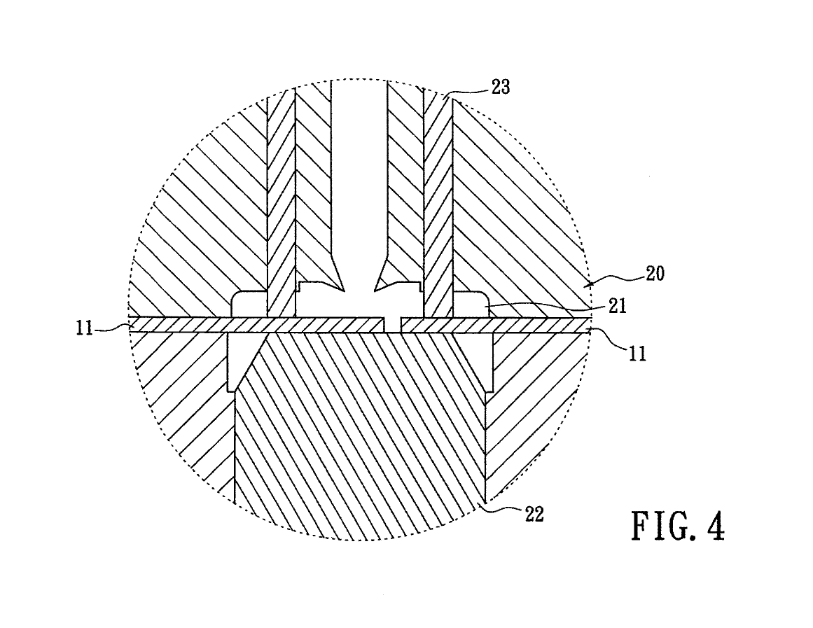

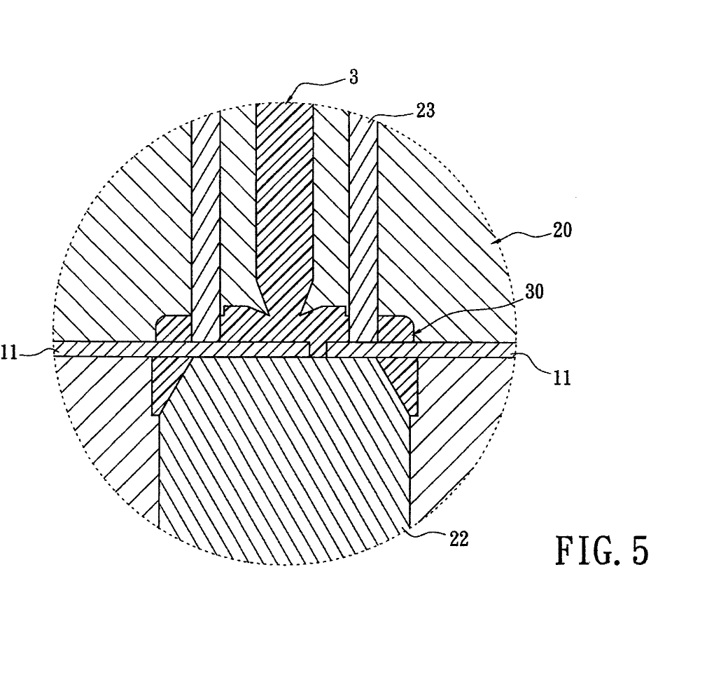

Referring to FIG. 1 to FIG. 5, the present invention provides the following steps:

(S100) Provides a metal substrate 1. The metal substrate 10 is a thin board. The metal substrate 10 is punched to form a plurality of metal pins 11 that are disposed at intervals and are not connected together by continuous feeding. The number of the metal pins 11 is not limited. The number of the metal pins 11 is two in the present invention.

(S101) Provides a mold 20 with a male and a female mold. The inside of the mold 20 has a predetermined shaped molding cavity 21 formed by a discharging process and so on. The molding cavity 21 has a forming bolt 22 and a plurality of corresponding positioning bolts 23. The shape of the forming bolt 22 can be a circle, square, a rectangle or a polygon. The shape of the forming bolt 22 is oblong in the present invention.

(S102) The metal substrate 10 is positioned in the mold 20 to the metal pins 11 disposed in the molding cavity 21. The forming bolt 22 and the positioning bolts 23 respectively abut against two opposite sides of the metal pins 11 for attaching the metal pins 11.

(S103) Providing and pouring a polymer material 3 into the molding cavity 21 by injection molding or casting molding or any other kind of molding method to cover the forming bolt 22, the positioning bolts 23 and the metal pins 11. The molding cavity 21 is also filled by the described molding method. The polymer material 3 can be polyphthalamide (PPA) or any other kind of thermoplastic resin.

(S104) The polymer material 3 is cooled and solidified to form an insulating plastic seat 30.

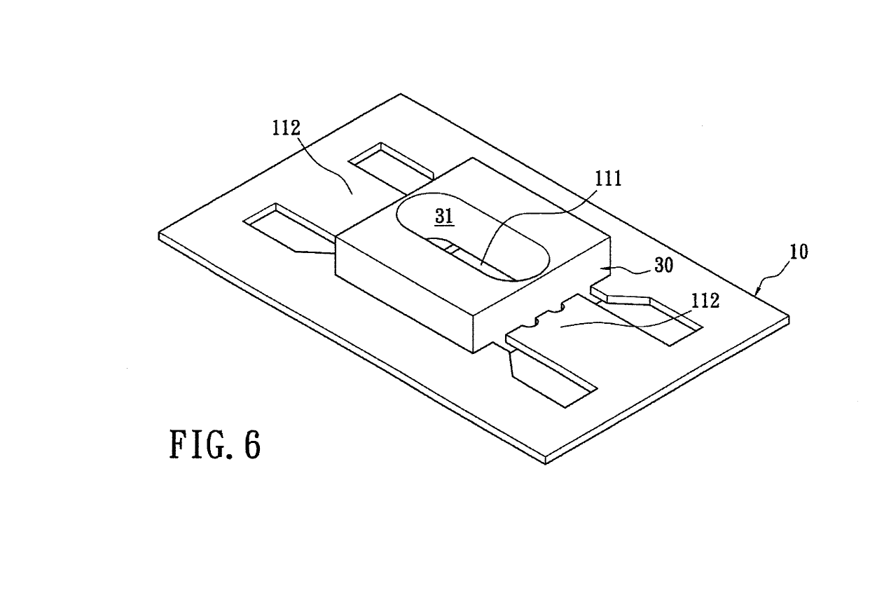

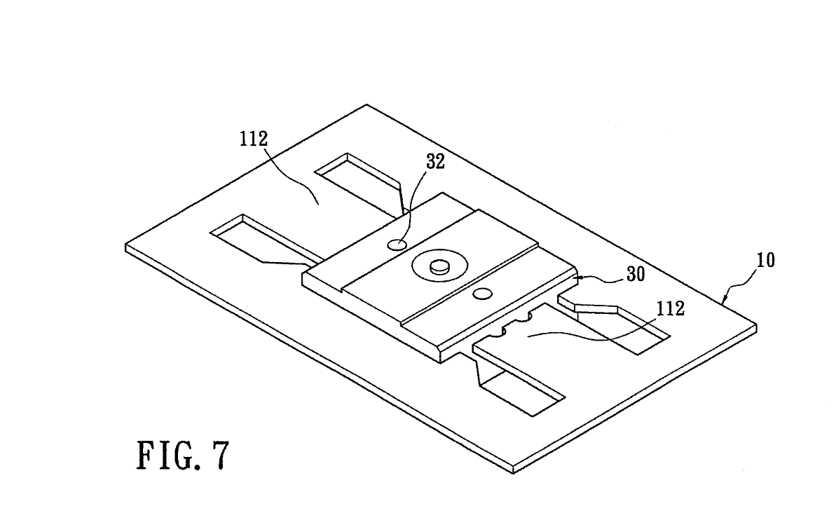

(S105) The forming bolt 22 and the positioning bolts 23 are removed to obtain the metal substrate 10 from the mold 20 by ejection molding and so on. Please refer to FIG. 6 and FIG. 7. One side of the plastic seat 30 has a concave functional area 31 formed thereon via the forming bolt 22, and the opposite side of the plastic seat 30 has a plurality of reserved holes 32 formed thereon by the positioning bolts 23. The metal pins 11 respectively extend outwardly to the outside of the plastic seat 30 from the functional area 31, and the reserved holes 32 communicate with the side of the metal pins 11.

The step before or the step after the punching of the metal substrate (S100), further comprises an electroplating step to the side of the metal pins that have a metallic reflection layer. Thereby the metal substrate 10 and the side of the pins have a metallic reflection layer respectively formed thereon (not shown). The metallic reflection layer is a highly reflective metal such as silver.

The present invention further provides structure an SMD diode frame which includes a plastic seat 30 and a plurality of metal pins 11. One side of the plastic seat 30 has a concave functional area 31 and the opposite side of the plastic seat 30 has a plurality of concave reserved holes 32. The plurality of metal pins 11 is respectively disposed on the plastic seat 30 at intervals and respectively extends outwardly to the outside of the plastic seat 30 from the functional area 31. Furthermore, the reserved holes 32 communicate with the side of the metal pins 11.

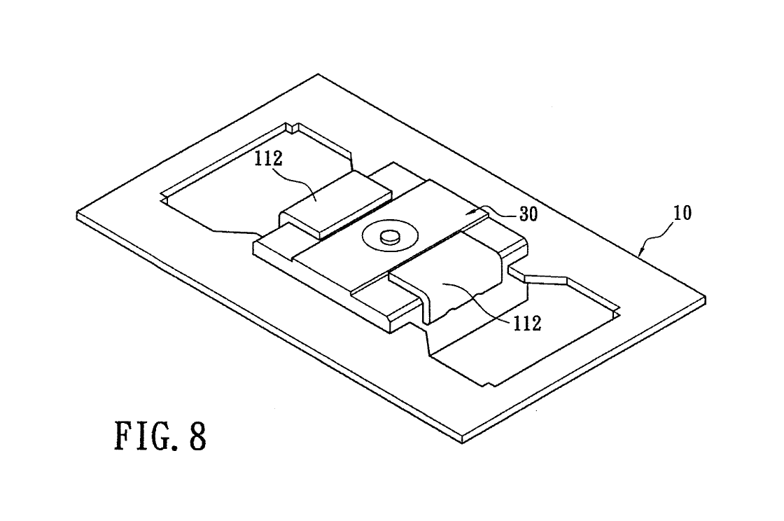

Furthermore, each of the metal pins 11 respectively has a base 111 and a pin portion 112. The base 111 is disposed in the functional area 31, and the pin portion 112 is extended to the outside of the plastic seat 30 from a side of the base 111. The pin portions 112 are disposed on two corresponding sides of the plastic seat 30 and bent to the reserved holes 32 of the plastic seat 30 (FIG. 8), thereby to form a Top view diode frame (positive direction luminescence). The pin portions 112 and the plastic seat 30 are on the same plane, thereby to form a Side view diode frame (lateral luminescence) (not shown).

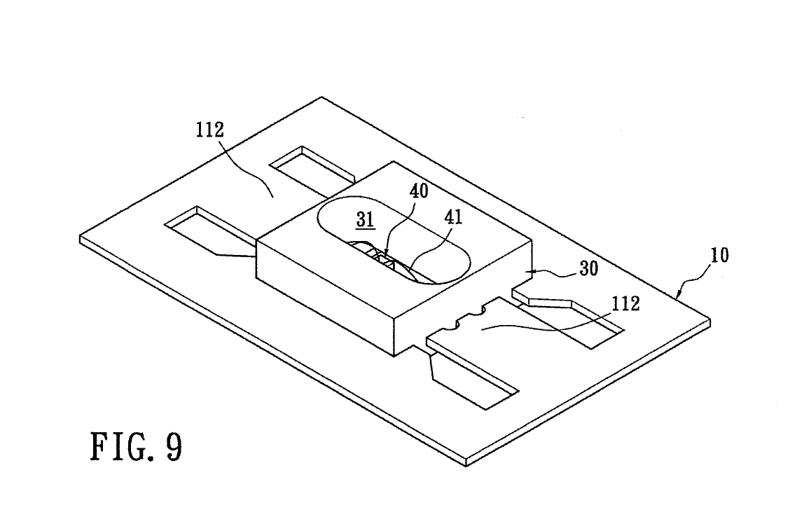

Referring to FIG. 9, the plastic seat 30 forms an SMD LED via a die bonding (method), a wire bonding (method) or packaging (method). In the die bonding method, the LED chip 40 is disposed on the base 111 of the metal pins 11 of the plastic seat 30 by an adhesion method or other similar methods. For wire bonding, the LED chip 40 is electrically connected with the base 111 of the metal pins 11 of the functional area 31 by a wire 41 (such as a gold wire). For package, the package layer with penetrability is covered over the functional area 31 of the plastic seat 30 (not shown). The package layer can be an epoxy resin or a thermoplastic resin. The electric current is supplied to the pin portions 112 of the metal pins 11 to the LED chip 40 is luminance. The electric current supplied to the pin portions 112 of the metal pins 11 lights the LED chip 40.

The advantages of the present invention as below:

(1). The forming bolt 22 and the positioning bolts 23 respectively abut against two opposite sides of the metal pins 11 so that the metal pins 11 are not displaced in the molding cavity 21.

(2). The plastic seat 30 sized accurately, produces a high yield at a low cost and is suitable for mass production.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A method for manufacturing an SMD diode frame, comprising:
providing and punching a metal substrate to form a plurality of metal pins which are disposed at intervals and are not connected together;
providing a mold having a predetermined shaped molding cavity, wherein the molding cavity has a forming bolt and a plurality of corresponding positioning bolts;
positioning the metal substrate in the mold to the metal pins disposed in the molding cavity, wherein the forming bolt and the positioning bolts respectively abut against two opposite sides of the metal pins;
providing and pouring a polymer material into the molding cavity to cover the forming bolt, the positioning bolts, and the metal pins;
cooling and solidifying the polymer material to form an insulating plastic seat; and
removing the forming bolt and the positioning bolts to obtain the metal substrate from the mold, wherein one side of the plastic seat has a concave functional area formed via the forming bolt, and the opposite side of the plastic seat has a plurality of reserved holes formed via the positioning bolts, and the metal pins respectively extend outwardly to an outside of the plastic seat from the functional area, and the reserved holes communicate with the side of the metal pins.

2. The method as claimed in claim 1, wherein the polymer material pours into the molding cavity via an injection molding method.

3. The method as claimed in claim 1, wherein the polymer material pours into the molding cavity via a cast molding method.

4. The method as claimed in claim 1, wherein before the punching of the metal substrate step, the method further comprises a step of electroplating the side of the metal pins with a metallic reflection layer.

5. The method as claimed in claim 1, wherein after the punching of the metal substrate step, the method further comprises a step of electroplating the side of the metal pins with a metallic reflection layer.

6. A structure for an SMD diode frame, comprising:
a plastic seat, wherein one side of the plastic seat has a concave functional area and the opposite side of the plastic seat has a plurality of concave reserved holes; and
a plurality of metal pins respectively disposed on the plastic seat at intervals and respectively extending outwardly to the outside of the plastic seat from the functional area, wherein the reserved holes communicate with the side of the metal pins.

7. The structure as claimed in claim 6, wherein each reserved hole is formed by a forming bolt.

8. The structure as claimed in claim 6, wherein the reserved holes are disposed on the side of the plastic seat at intervals.

9. The structure as claimed in claim 6, wherein the surface of the metal pins respectively has a metallic reflection layer.

10. The structure as claimed in claim 6, wherein the metal pins each have a base and a pin portion, the base is disposed in the functional area, and the pin portion extends to the outside of the plastic seat from the side of the base.

11. The structure as claimed in claim 10, wherein the pin portions are disposed on two corresponding sides of the plastic seat.

12. The structure as claimed in claim 10, wherein the pin portions and the plastic seat are on the same plane.
